(19) United States
(12) Patent Application Publication
(10) Pub. No.: US 2023/0103147 A1
(43) Pub. Date: Mar. 30, 2023

(54) LOW STRESS PLANE DESIGN FOR IC PACKAGE SUBSTRATE

(71) Applicant: NVIDIA Corporation, Santa Clara, CA (US)

(72) Inventors: Yuanjing Jane Li, Saratoga, CA (US); Chuan Zhang, San Jose, CA (US); John Aguada, Milpitas, CA (US); Howard Marks, Gilroy, CA (US)

(21) Appl. No.: 17/490,987

(22) Filed: Sep. 30, 2021

(51) Int. Cl. H05K 1/02; H05K 3/12; H05K 3/46

(52) U.S. Cl. CPC H05K 1/0271; H05K 3/1275; H05K 3/4644; H05K 2203/0551; H05K 2201/093

(57) ABSTRACT

It is desirable to improve a longevity and reliability of a substrate used within an IC package. By modifying a design of the one or more layout masks used to create planes within a substrate, the resulting planes may have a non-straight pattern on the edges of each plane and may include a predetermined pattern of open spaces filled with dielectric materials in each plane. The improved mechanical strength of the patterned planes can effectively compensate the effect of mismatched thermal expansion during IC testing and deployment, resulting in increased durability and longevity of the package substrates.

### FIELD OF THE INVENTION

The present invention relates to circuit design and implementation, and more particularly to optimizing planes within a substrate of a circuit.

### BACKGROUND

Substrates are commonly used during the creation of integrated circuit (IC) packages to facilitate communications between the IC and a printed circuit board (PCB). However, current substrate designs have physical reliability issues that arise during testing and real-world deployment of the IC packages. For example, thermal expansion during testing and deployment may cause current substrates to warp and/or break. There is therefore a need to adjust these substrates to increase their longevity and reliability.

### BRIEF DESCRIPTION OF THE DRAWINGS

FIG. 1 illustrates a flowchart of a method for creating modified planes within a substrate, in accordance with an embodiment.

FIG. 2 illustrates an exemplary system in which the various architecture and/or functionality of the various previous embodiments may be implemented.

FIG. 3 illustrates an exemplary modified substrate, in accordance with an embodiment.

FIG. 4 illustrates a flowchart of a method for modifying a substrate creation process to include modified planes, in accordance with an embodiment.

### DETAILED DESCRIPTION

It is desirable to improve a longevity and reliability of a substrate used within an IC package. By modifying a design of the one or more layout masks used to create conductive metal planes within a substrate, the resulting planes may have a non-straight pattern on the edges of each plane and may include a predetermined pattern of open spaces filled with dielectric materials in each plane. The improved mechanical strength of the patterned planes can effectively compensate the adverse effect of mismatched thermal expansion during IC testing and deployment, resulting in increased durability and longevity of the package substrates.

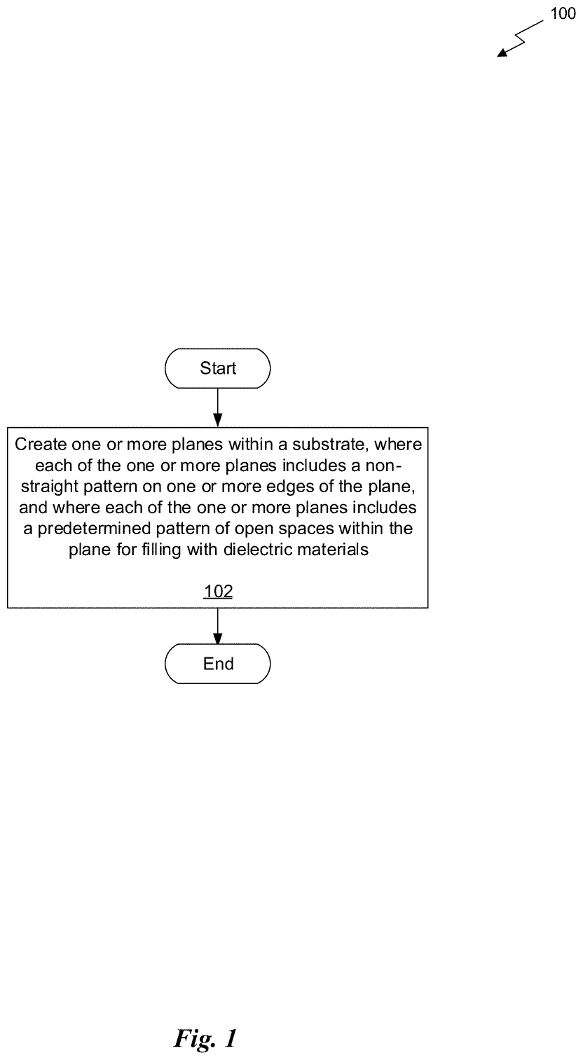

FIG. 1 illustrates a flowchart of a method 100 for creating modified planes within a substrate, in accordance with an embodiment. Although method 100 is described in the context of a processing unit, the method 100 may also be performed by a program, custom circuitry, or by a combination of custom circuitry and a program. For example, the method 100 may be executed by a GPU (graphics processing unit), CPU (central processing unit), or any processing element. Furthermore, persons of ordinary skill in the art will understand that any system that performs method 100 is within the scope and spirit of embodiments of the present invention.

As shown in operation 102, one or more planes are created within a substrate, where each of the one or more planes includes a non-straight pattern on one or more edges of the plane, and where each of the one or more planes includes a predetermined pattern of open spaces within the plane filled with dielectric materials. In one embodiment, the substrate may include a material used to package one or more bare integrated circuit (IC) chips. For example, the IC may include one or more electronic circuits on a flat piece of semiconductor material (e.g., silicon, etc.). In another example, the IC may include a silicon die. For example, the IC may include a graphics processing unit (GPU), a central processing unit (CPU), etc.

Additionally, in one embodiment, an IC may be mounted on the substrate. For example, a silicon die may be packaged on the substrate. In another embodiment, the substrate may be connected (e.g., surface mounted, etc.) to a printed circuit board (PCB). In this way, the substrate may act as an interface between the IC and the PCB. For example, the substrate may provide power and/or communications from the PCB to the IC.

Further, in one embodiment, the substrate may include one or more layers. In another embodiment, the one or more planes may be implemented within one or more of the layers of the substrate. In still another embodiment, the one or more planes may include a power plane, a ground plane, etc. For example, the power plane may provide power to the IC mounted on the substrate. In another example, the ground plane may provide a ground connection to the IC mounted on the substrate. In another embodiment, the power plane and the ground plane may comprise different portions of a single substrate layer.

Further still, in one embodiment, the edges of the plane may include the sides of the plane. In another embodiment, the edges of a first plane may include the location where the first plane contacts a second plane different from the first plane within the substrate. In yet another embodiment, the non-straight pattern may include a serrated (e.g., zig-zag) pattern. In this way, the non-straight pattern on the edges of the plane may stop an increase and/or propagation of cracks within the plane.

Also, in one embodiment, the predetermined pattern of open spaces within the plane may include a plurality of geometric holes within the surface of the plane. In another embodiment, the geometric holes may include one or more circles and/or any other geometric shapes or combinations of shapes. In yet another embodiment, the predetermined pattern of open spaces may have a varying shape, size, density, and/or distribution. For example, the shape, size, density, and/or distribution of the pattern of holes may change within the one or more planes.

In addition, in one embodiment, the pattern may be asymmetrical, symmetrical, etc. In this way, the predetermined pattern of open spaces within a plane may increase a flexibility of the plane and may reduce thermomechanical stress within and surrounding the plane during testing/deployment. In one embodiment, the dielectric materials may include an electrical insulator that can be polarized by applying an electric field. In another embodiment, the dielectric materials may be applied in liquid form to the pattern.

Furthermore, in one embodiment, each of the one or more planes may be created utilizing one or more layout masks. For example, each of the one or more planes may be constructed from a solid metal conductor sheet (e.g., a copper sheet, etc.). In another example, a photolithography exposure may be performed utilizing the one or more layout masks to create the design for each of the one or more planes. In yet another example, the one or more layout masks may dictate the design that is created using the photolithography process.

Further still, in one embodiment, a design of the one or more layout masks may be modified to include the non-straight pattern on one or more edges of the plane and/or the predetermined pattern of open spaces within the plane. For example, a photolithography exposure may be performed utilizing the one or more modified layout masks to create the design for each of the one or more planes having the non-straight pattern on the edges of the plane and/or the predetermined pattern of open spaces within the plane.

In this way, by adjusting the edges and surface of planes within a substrate, the planes may be more resistant to thermal expansion during IC testing and deployment. This may improve the longevity and reliability of the substrate and any integrated circuit (IC) package utilizing the substrate.

More illustrative information will now be set forth regarding various optional architectures and features with which the foregoing framework may be implemented, per the desires of the user. It should be strongly noted that the following information is set forth for illustrative purposes and should not be construed as limiting in any manner. Any of the following features may be optionally incorporated with or without the exclusion of other features described.

### Exemplary Architecture

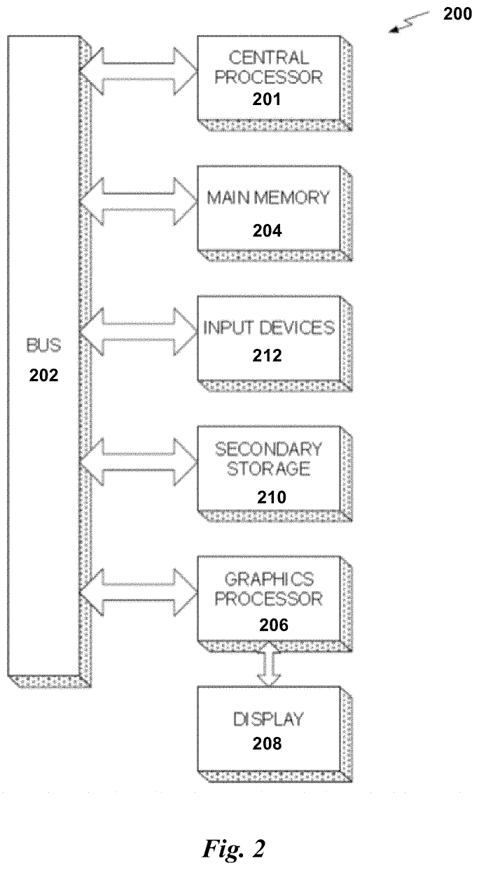

FIG. 2 illustrates an exemplary system 200 in which the various architecture and/or functionality of the various previous embodiments may be implemented. As shown, a system 200 is provided including at least one central processor 201 that is connected to a communication bus 202. The communication bus 202 may be implemented using any suitable protocol, such as PCI (Peripheral Component Interconnect), PCI-Express, AGP (Accelerated Graphics Port), HyperTransport, or any other bus or point-to-point communication protocol(s). The system 200 also includes a main memory 204. Control logic (software) and data are stored in the main memory 204 which may take the form of random access memory (RAM).

The system 200 also includes input devices 212, a graphics processor 206, and at least one display 208, i.e. a conventional CRT (cathode ray tube), LCD (liquid crystal display), LED (light emitting diode), plasma display or the like. User input may be received from the input devices 212, e.g., keyboard, mouse, touchpad, microphone, and the like. In one embodiment, the graphics processor 206 may include a plurality of shader modules, a rasterization module, etc. Each of the foregoing modules may even be situated on a single semiconductor platform to form a graphics processing unit (GPU).

In the present description, a single semiconductor platform may refer to a sole unitary semiconductor-based integrated circuit or chip. It should be noted that the term single semiconductor platform may also refer to multi-chip modules with increased connectivity which simulate on-chip operation, and make substantial improvements over utilizing a conventional central processing unit (CPU) and bus implementation. Of course, the various modules may also be situated separately or in various combinations of semiconductor platforms per the desires of the user.

The system 200 may also include a secondary storage 210. The secondary storage 210 includes, for example, a hard disk drive and/or a removable storage drive, representing a floppy disk drive, a magnetic tape drive, a compact disk drive, digital versatile disk (DVD) drive, recording device, universal serial bus (USB) flash memory, solid state drive (SSD), etc. The removable storage drive reads from and/or writes to a removable storage unit in a well-known manner.

Computer programs, or computer control logic algorithms, may be stored in the main memory 204 and/or the secondary storage 210. Such computer programs, when executed, enable the system 200 to perform various functions. The memory 204, the storage 210, and/or any other storage are possible examples of computer-readable media.

In one embodiment, the architecture and/or functionality of the various previous figures may be implemented in the context of the central processor 201, the graphics processor 206, an integrated circuit (not shown) that is capable of at least a portion of the capabilities of both the central processor 201 and the graphics processor 206, a chipset (i.e., a group of integrated circuits designed to work and sold as a unit for performing related functions, etc.), and/or any other integrated circuit for that matter. Further still, the circuit may be realized in reconfigurable logic. In one embodiment, the circuit may be realized using an FPGA (field gate programmable array).

Still yet, the architecture and/or functionality of the various previous figures may be implemented in the context of a general computer system, a circuit board system, a game console system dedicated for entertainment purposes, an application-specific system, and/or any other desired system. For example, the system 200 may take the form of a desktop computer, laptop computer, server, workstation, game consoles, embedded system, and/or any other type of logic. Still yet, the system 200 may take the form of various other devices including, but not limited to a personal digital assistant (PDA) device, a mobile phone device, a television, etc.

Further, while not shown, the system 200 may be coupled to a network (e.g., a telecommunications network, local area network (LAN), wireless network, wide area network (WAN) such as the Internet, peer-to-peer network, cable network, or the like) for communication purposes.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

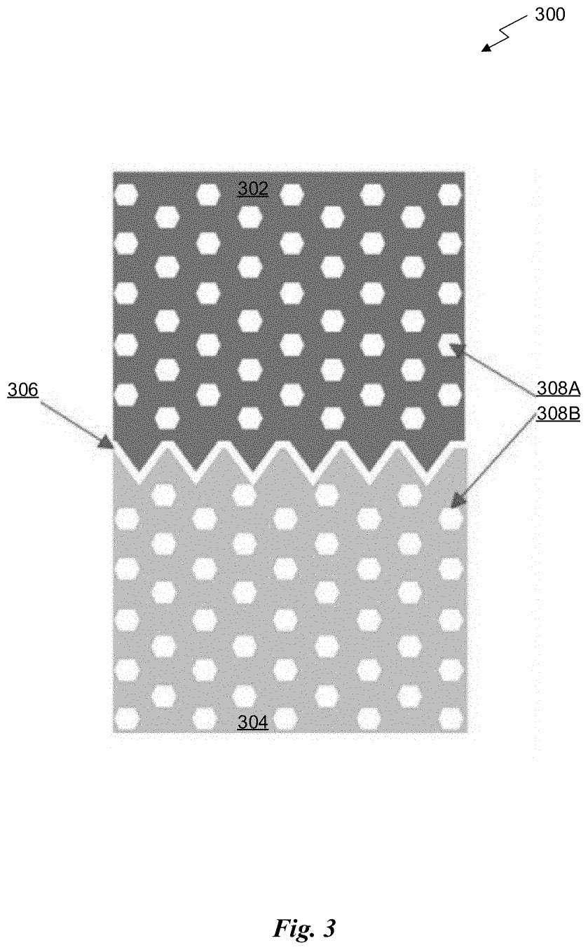

FIG. 3 illustrates an exemplary modified substrate 300, according to one embodiment. As shown, the exemplary modified substrate 300 includes a power plane 302 and a ground plane 304. Both the power plane 302 and the ground plane 304 have a serrated edge 306. Additionally, both the power plane 302 and a ground plane 304 have a predetermined pattern of open spaces 308A and 308B within the respective plane.

It should be noted that although the predetermined pattern of open spaces 308A and 308B is shown as a plurality of evenly spaced hexagonal holes, the open spaces may be any combination of geometric shapes of varying size, density, and/or distribution.

In this way, the serrated edge 306 of the power plane 302 and the ground plane 304, as well as the predetermined pattern of open spaces 308A and 308B within the power plane 302 and the ground plane 304, respectively, may enhance substrate reliability during IC testing and deployment.

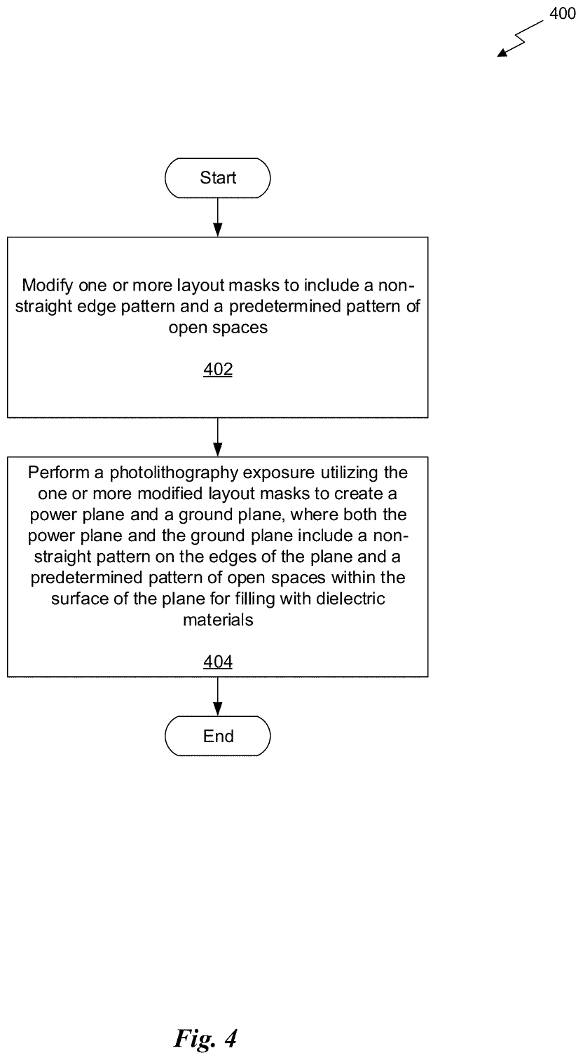

FIG. 4 illustrates a flowchart of a method 400 for modifying a substrate creation process to include modified planes, in accordance with an embodiment. Although method 400 is described in the context of a processing unit, the method 400 may also be performed by a program, custom circuitry, or by a combination of custom circuitry and a program. For example, the method 400 may be executed by a GPU (graphics processing unit), CPU (central processing unit), or any processing element. Furthermore, persons of ordinary skill in the art will understand that any system that performs method 400 is within the scope and spirit of embodiments of the present invention.

As shown in operation 402, one or more layout masks are modified to include a non-straight edge pattern and a predetermined pattern of open spaces. In one embodiment, portions of the one or more layout masks may be added and/or removed to perform the modification.

Additionally, as shown in operation 404, a photolithography exposure is performed utilizing the one or more modified layout masks to create a power plane and a ground plane, where both the power plane and the ground plane include a non-straight pattern on the edges of the plane and a predetermined pattern of open spaces within the surface of the plane for filling with dielectric materials.

In one embodiment, each of the one or more planes may be constructed from a solid metal conductor sheet (e.g., a copper sheet, etc.). In another embodiment, the one or more layout masks may dictate the design that is created using the photolithography process.

In this way, the power plane and the ground plane may be constructed to achieve enhanced substrate reliability during IC testing and deployment, based on the modified design of one or more layout masks of such planes.

### Low Stress Power/Ground Plane Geometric Layout Pattern Design for IC Package Substrate

This invention addresses the high-rate reliability failures associated with thermo-mechanical stress-induced cracking of substrate materials along the edges of power or ground planes in IC package substrates.

Due to a mismatch in coefficient of thermal expansion (CTE) between silicon die and substrate materials, there is a continuous change in package warpage during temperature cycle reliability tests. According to an exemplary finite element model simulation on IC products, the thermo-mechanical stress tends to peak at the edges of power or ground planes, where the substrate material strength is weakest due to the abrupt transition of the mechanical properties at the materials interface.

Any fine separation at the interface between the two materials could easily propagate along the edge interface of the plane, leading to a substrate failure. Large and high-performance IC chips tend to be more vulnerable to higher thermal stress close to the edge of chip, and therefore substrate cracking failures.

Eliminating this type of failures is important for ensuring the reliability of IC package products. No previous solutions could effectively reduce the stress at the plane interfaces and effectively reduce the risk of substrate failures.

Conventional package substrates have the layout design of solid power or ground planes with straight and smooth edges in between. This invention uses zigzag and some other non-straight edge patterns instead of straight edges for the planes. With the design, the chance of cracking would be much lower. The design of the abrupt change in the direction of the edge interface in the zigzag edge can effectively obstruct the propagation of a crack from beginning.

Additionally, geometric patterns are strategically added into the solid power or ground planes to enhance the homogeneity of the substrate materials. As a result, 1) plane flexibility is improved; 2) stress at the plane edges is more evenly redistributed; and 3) the attachment of the power/ground planes to the substrate dielectrics is stronger, making it less likely for materials to separate and delaminate at the interfaces. Consequently, the overall stability and reliability of the IC package may improve.

The change in the geometric patterns of the planes may be achieved through a modification of layout masks of the substrate layers.

No prior methods can effectively improve the intrinsic structural substrate weakness due to the stress concentration at the straight edges of power and ground planes. However, in this invention, the package substrate stress is redistributed, and high stress points are evened out by deliberating the layout geometry for power and ground planes. With greater material flexibility and homogeneity, the substrate will be less prone to cracking. As a result, improvement in the overall device reliability will be achieved.

Our layout design scheme uses patterned power and ground planes with holes in planes and zigzag gap at the edges between planes. As a result of the geometric shapes, 1) straight-line crack propagation at the edge of the planes is discouraged; and 2) metal planes are better fastened in the dielectrics, which can effectively stop the shear stress-induced plane delamination. Overall thermo-mechanical stability of package substrate will be improved.

The above benefits may be achieved via modifications to the photolithography masks of the substrate trace layers, and allows the use of mainstream substrate fabrication process.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including handheld devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

1. A method comprising, at a device:
creating one or more planes within a substrate,
wherein each of the one or more planes includes a non-straight pattern on one or more edges of the plane.

2. The method of claim 1, wherein substrate includes a material used to package one or more bare integrated circuit (IC) chips.

3. The method of claim 1, wherein the substrate includes one or more layers, and the one or more planes are implemented within one or more of the layers of the substrate.

4. The method of claim 1, wherein the one or more planes include a power plane.

5. The method of claim 1, wherein the one or more planes include a ground plane.

6. The method of claim 1, wherein the edges of a first plane include a location where the first plane contacts a second plane different from the first plane within the substrate.

7. The method of claim 1, wherein the non-straight pattern includes a serrated pattern.

8. (canceled)

9. A method comprising, at a device:
creating one or more planes within a substrate,
wherein each of the one or more planes includes a predetermined pattern of open spaces within a surface of the plane.

10. The method of claim 9, wherein substrate includes a material used to package one or more bare integrated circuit (IC) chips.

11. The method of claim 9, wherein the substrate includes one or more layers, and the one or more planes are implemented within one or more of the layers of the substrate.

12. The method of claim 9, wherein the one or more planes include a power plane.

13. The method of claim 9, wherein the one or more planes include a ground plane.

14. The method of claim 9, wherein the predetermined pattern of open spaces within the surface of the plane includes a plurality of geometric holes within the plane.

15. The method of claim 9, wherein the predetermined pattern of open spaces has a varying shape, size, density, and distribution.

16. The method of claim 9, wherein the pattern is asymmetrical.

17. The method of claim 9, wherein the pattern is symmetrical.

18. (canceled)

19. (canceled)

20. (canceled)

21. A non-transitory computer-readable storage medium storing instructions that, when executed by a processor of a device, causes the processor to cause the device to:
create one or more planes within a substrate,
wherein each of the one or more planes includes one or more of:
a non-straight pattern on one or more edges of the plane, and
a predetermined pattern of open spaces within a surface of the plane.

22. A substrate used to package one or more bare integrated circuit (IC) chips, the substrate including:
one or more planes,
wherein at least one of the one or more planes includes one or more of:
a non-straight pattern on one or more edges of the plane, and
a predetermined pattern of open spaces within a surface of the plane.

23. The substrate of claim 22, wherein the substrate includes one or more layers, and the one or more planes are implemented within one or more of the layers of the substrate.

24. The substrate of claim 22, wherein the one or more planes include a power plane.

25. The substrate of claim 22, wherein the one or more planes include a ground plane.

26. The substrate of claim 22, wherein the edges of a first plane include a location where the first plane contacts a second plane different from the first plane within the substrate.

27. The substrate of claim 22, wherein the non-straight pattern includes a serrated pattern.

28. The substrate of claim 22, wherein the predetermined pattern of open spaces within the surface of the plane includes a plurality of geometric holes within the plane.

29. The substrate of claim 22, wherein the predetermined pattern of open spaces has a varying shape, size, density, and distribution.

30. The substrate of claim 22, wherein the pattern is asymmetrical.

31. The substrate of claim 22, wherein the pattern is symmetrical.
